(19) United States
(12) Patent Application Publication
(10) Pub. No.: US 2017/0062385 A1
(43) Pub. Date: Mar. 2, 2017

(54) POWER CONVERTING DEVICE

(71) Applicant: Electronics and Telecommunications Research Institute, Daejeon (KR)

(72) Inventors: Dong Yun JUNG, Daejeon (KR); Sang Choon KO, Daejeon (KR); Chi Hoon JUN, Daejeon (KR); Minki KIM, Daejeon (KR); Jeho NA, Seoul (KR); EUN SOO NAM, Daejeon (KR); Young Rak PARK, Daejeon (KR); Junbo PARK, Seoul (KR); Hyun Soo LEE, Goyang-si (KR); Hyung Seok LEE, Daejeon (KR); Hyun-Gyu JANG, Cheongju-si (KR)

(73) Assignee: Electronics and Telecommunications Research Institute, Daejeon (KR)

(21) Appl. No.: 15/221,089

(22) Filed: Jul. 27, 2016

(30) Foreign Application Priority Data
Aug. 28, 2015 (KR) 10-2015-0122075
Feb. 22, 2016 (KR) 10-2016-0020723

(51) Int. Cl. H01L 25/065; H01L 29/78; H01L 23/522; H01L 23/528; H02M 3/158; H01L 23/373

(52) U.S. Cl. CPC H01L 25/0652; H02M 3/158; H01L 23/3736; H01L 23/5226; H01L 23/528; H01L 29/78

(57) ABSTRACT

Disclosed is a power converting device including: a first laminate having a plurality of non-magnetic substrates which are laminated; electronic devices disposed on at least one of the non-magnetic substrates; first conductive patterns disposed on the non-magnetic substrate on which the electronic devices are disposed, the first conductive patterns being connected to the electronic devices; at least one via electrode connecting the respective first conductive patterns to each other; a second laminate disposed on one side of the first laminate and having a plurality of magnetic sheets which are laminated; second conductive patterns disposed on at least two magnetic sheets among the plurality of magnetic sheets; and at least one via electrode connecting the respective second conductive patterns to each other, wherein the first and second via electrodes are connected to each other.

### CROSS-REFERENCE TO RELATED APPLICATIONS

This U.S. non-provisional patent application claims priorities under 35 U.S.C. §119 of Korean Patent Application Nos. 10-2015-0122075, filed on Aug. 28, 2015, and 10-2016-0020723, filed on Feb. 22, 2016, the entire contents of which are hereby incorporated by reference.

### BACKGROUND

The present disclosure herein relates to a power converting device.

A power converting device has been widely used as an important core technology in various application fields such as a DC/DC converter for communications, a UPS, an inverter, a motor drive, an electric charger, and a photovoltaic power generation. Such a power converting device has been used for communications as well as for a mobile phone having a limited space in size or volume. Further, the power converting device has also been used in a new and renewable energy field where a supply of a converted power is highly reliable and a conversion capacity thereof is high. Thus, miniaturization and an increase of conversion capacity of the power converting device are increasingly demanded.

### SUMMARY

The present disclosure provides a miniaturized power converting device.

An object of the present disclosure is not limited to the aforesaid, but other objects not described herein will be clearly understood by those skilled in the art from descriptions below.

An embodiment of the inventive concept provides a power converting device including: a first laminate having a plurality of non-magnetic substrates which are laminated; electronic devices disposed on at least one of the non-magnetic substrates; first conductive patterns disposed on the non-magnetic substrate on which the electronic devices are disposed, the first conductive patterns being connected to the electronic devices; at least one first via electrode connecting the respective first conductive patterns to each other; a second laminate disposed on one side of the first laminate and having a plurality of magnetic sheets which are laminated; second conductive patterns disposed on at least two of the magnetic sheets among the plurality of magnetic sheets; and at least one second via electrode connecting the respective second conductive patterns to each other, and the first via electrode and the second via electrode are connected to each other.

In an embodiment, each of the magnetic sheets may be a ferrite sheet.

In an embodiment, the non-magnetic sheet may be a low temperature co-fired ceramic (LTCC) substrate.

In an embodiment, the first conductive patterns and the second conductive patterns may include a metallic material.

In an embodiment, the power converting device may further include a heat sink disposed on one side of the second laminate.

In an embodiment, the power converting device may further include a dummy adhesive layer disposed between the second laminate and the heat sink to bond the second laminate and the heat sink.

In an embodiment, the power converting device may further include a molding film disposed on the first laminate.

In an embodiment, at least one of the first conductive patterns may include a lead pattern connected to an external terminal.

In an embodiment, the non-magnetic substrate may include first via holes through which the first via electrode passes, and the magnetic sheet may include second via holes through which the second via electrode passes.

In an embodiment, each of the first via holes and each of the second via holes may be disposed on the same line.

Particularities of other embodiments are included in the detailed description and drawings.

### BRIEF DESCRIPTION OF THE FIGURES

The accompanying drawings are included to provide a further understanding of the inventive concept, and are incorporated in and constitute a part of this specification. The drawings illustrate exemplary embodiments of the inventive concept and, together with the description, serve to explain principles of the inventive concept. In the drawings:

FIG. 1 is a perspective view of a power converting device according to an embodiment of the inventive concept;

FIG. 2 is a cross-sectional view taken along line I-I′ of FIG. 1;

FIG. 3 is an exploded perspective view illustrating a magnetic material section of the power converting device of FIG. 1;

FIG. 4 is a circuit diagram illustrating a configuration of the power converting device of FIG. 1;

FIGS. 5 to 13 are cross-sectional views illustrating a manufacturing process of the power converting device of FIG. 1; and

FIG. 14 is a perspective view illustrating a power converting device according to another embodiment of the inventive concept.

### DETAILED DESCRIPTION

Exemplary embodiments of the inventive concept will be described below in more detail with reference to the accompanying drawings. The inventive concept may, however, be embodied in different forms and should not be construed as limited to the embodiments set forth herein. Rather, these embodiments are provided so that this disclosure will be thorough and complete, and will fully convey the scope of the inventive concept to those skilled in the art. In the drawings, the dimensions of elements are exaggerated for convenience in description and clarity, and the ratio of each element may be scaled up or down.

It will be understood that when one element is referred to as being “on” or “connected to” another element, the former may be directly on or connected to the latter or an intervening element may be present. On the contrary, when one element is referred to as being “directly on” or “directly connected to” another element, it should be understood that the former is connected to the latter without an intervening element therebetween. Other expressions for describing the positional relationship between elements, such as “between”, “directly between” or “adjacent to” or “directly adjacent to” should be interpreted in the same manner as above.

Although terms like a first and a second are used to describe various elements, components, and/or sections in various embodiments of the inventive concept, the elements, components, and/or sections are not limited thereto. These terms are used only to differentiate one element, component, or section from another one. Accordingly, it will be apparent that a first element, a first component, or a first section described hereinafter may refer to a second element, a second component, or a second section within the scope of technical idea of the inventive concept. Likewise a second element, a second component, or a second section described hereinafter may refer to a first element, a first component, or a first section.

The terms of a singular form may include plural forms unless referred to the contrary. The meaning of “include”, “comprise”, “including”, “comprising”, “have”, or “having” specifies a characteristic, a fixed number, a step, a process, an element, a component and/or a combination thereof, but does not exclude other properties, fixed numbers, steps, processes, elements, components and/or combinations thereof.

Unless otherwise indicated herein, all the terms used in embodiments of the inventive concept may be interpreted as the same meaning that is generally understood by a person skilled in the art. Further, the terms of at least one is used as the same meaning as minimum one, and may selectively indicate one or more.

Hereinafter, the inventive concept and exemplary embodiments of the inventive concept will be described in detail with reference to the accompanying drawings.

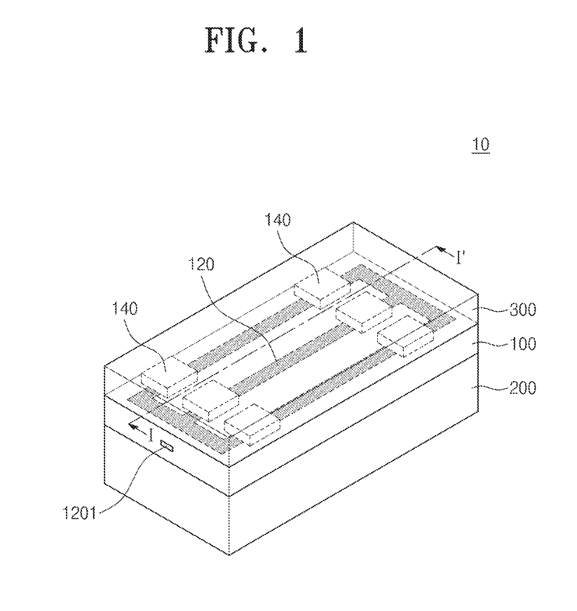

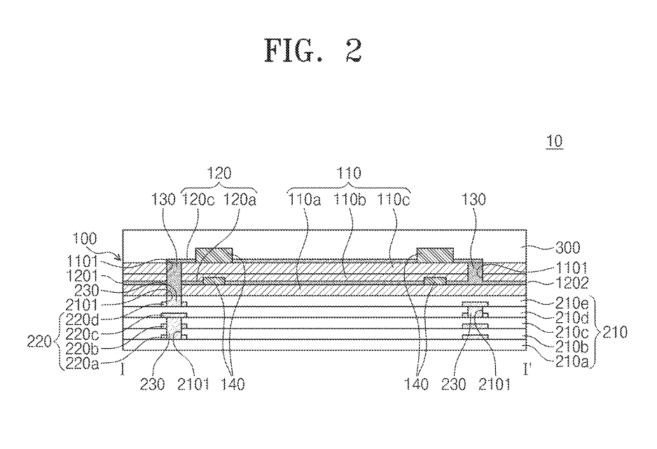

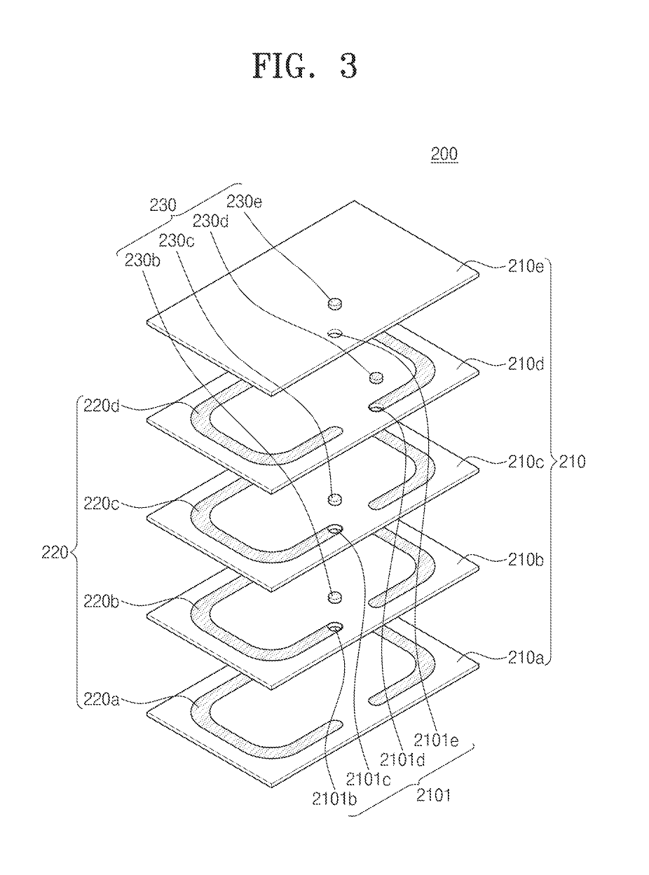

FIG. 1 is a perspective view illustrating a power converting device according to an embodiment. FIG. 2 is a cross-sectional view taken along line I-I′ of FIG. 1. FIG. 3 is an exploded perspective view illustrating a magnetic material section of the power converting device of FIG. 1.

Referring to FIGS. 1 to 3, a power converting device 10 according to an embodiment serves to convert a power assigned by an external power source to a stable and effective output power required by a system. The power converting device 10 may include an electronic device section 100, a magnetic material section 200 and a molding film 300.

The electronic device section 100 may include a first laminate 110, electronic devices 140, first conductive patterns 120, and a first via electrode 130.

The first laminate 110 may be disposed on a second laminate 210 of the magnetic material section 200 which will be later described. The first laminate 110 may have a structure in which a plurality of non-magnetic substrates 110a to 110c are laminated. In an embodiment, the first laminate 110 may have a structure in which a first non-magnetic substrate 110a, a second non-magnetic substrate 110b and a third non-magnetic substrate 110c are sequentially laminated. Each of the non-magnetic substrates 110a to 110c may be a ceramic substrate, but not limited thereto. For example, each of the non-magnetic substrates 110a to 110c may be a Low Temperature Co-fired Ceramic (LTCC) substrate. The first laminate 110 may be completed through a pressurizing and annealing process after the plurality of non-magnetic substrates 110a to 110c are laminated. Thus, the non-magnetic substrates 110a to 110c adjacent to each other may be integrated to such an extent that the boundaries therebetween are indistinguishable from each other.

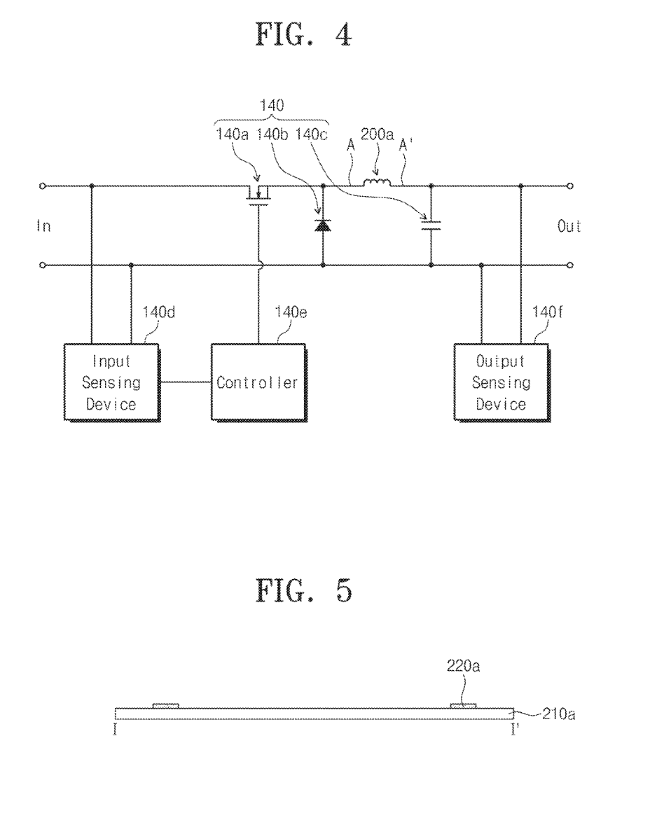

At least one electronic device 140 may be disposed on upper surfaces of the non-magnetic substrates 110a to 110c. The electronic device 140 may be a capacitor 140c (see FIG. 4), a switching device 140a (see FIG. 4), a transformer, a semiconductor device 140b (see FIG. 4), a controller 140e (e.g., gate driver, see FIG. 4), an input sensing device 140d (see FIG. 4), an output sensing device 140f (see FIG. 4) or the like. The semiconductor device 140b (see FIG. 4) may be replaced by a second switching device. At least one of the electronic devices 140 may be disposed between the non-magnetic substrates 110a to 110c adjacent to each other. In an embodiment, two electronic devices 140 may be disposed between the first non-magnetic substrate 110a and the second non-magnetic substrate 110b. Being disposed between the non-magnetic substrates 110a to 110c adjacent to each other, the electronic device 140 may be disposed inside the first laminate 110. Thus, the size of the power converting device 10 may be miniaturized by minimizing an area in which the electronic device 140 is mounted.

The non-magnetic substrates 110a to 110c may include first via holes 1101 through which the first via electrode 130 passes. The respective first via holes 1101 of the non-magnetic substrates 110a to 110c may be disposed to correspond to each other. Being disposed to correspond to each other may mean that each of the first via holes 1101 is formed at the same position in each of the non-magnetic substrates 110a to 110c. Accordingly, each of the first via holes 110 may be formed on the same line. In other words, the first via holes 1101 may be vertically overlapped with each other.

The first conductive patterns 120 are provided on the plurality of non-magnetic substrates 110a to 110c on which the electric devices 140 are disposed, and may be coupled to the electronic devices 140. Thus, an electric signal, a control signal and the like may be input to and/or output from the electronic devices 140 by the first conductive patterns 120.

The first conductive patterns 120 may be provided on the non-magnetic substrates 110a to 110c by means of a screen printing, a gravure electrode printing or the like. The first conductive patterns 120 may include a metal material. For example, the first conductive patterns 120 may include any one selected from Ag, Sn, Ni, Pt, Au, Cu or an alloy thereof, but not limited thereto.

At least one of the first conductive patterns 120 may include lead patterns 1201 and 1202 that are electrically connected to external terminals (not shown). For example, any one of the first conductive patterns 120 may include a first lead pattern 1201 connected to a positive external terminal (not shown) and a second lead pattern 1202 connected to a negative external terminal (not shown). Accordingly, electric power may be applied to the power converting device 10 from an external power source.

The first via electrode 130 may connect the first conductive patterns 120 to each other by penetrating through first via holes 1101 of the plurality of non-magnetic substrates 110a to 110c. Accordingly, the first via electrode 130 may electrically connect the first conductive patterns 120 to each other. In an embodiment, the first via electrode 130 may be two, but not limited thereto. In another embodiment, the first via electrode 130 may be one or three or more. The first via electrode 130 may be connected to a second via electrode 230 which will be later described. The first via electrode 130 may be formed of the conductive material filled in the first via holes 1101 each of which is formed in the non-magnetic substrates 110a to 110c. The first via electrode 130 may be formed of a conductive material such as Ag-based material or the like filled in the first via holes 1101 by means of a printing method.

The magnetic material section 200 may generate an inductance. The magnetic material section 200 may be provided under the electronic device section 100. The magnetic material section 200 may be connected to the electronic device section 100 by a conductive adhesive (not shown). As the magnetic material section 200 and the electronic device section 100 are connected together, the power converting device 10 may be designed to have a shortest distance between the magnetic material section 200 and the electronic device section 100, and thus the size of the power converting device 10 may be miniaturized. The magnetic material section 200 may include a second laminate 210, second conductive patterns 220, and a second via electrode 230.

The second laminate 210 may be provided on one side of the first laminate 110. For example, the second laminate 210 may be provided under the first laminate 110. The second laminate 210 may have a structure in which a plurality of magnetic sheets 210a to 210e are laminated. Accordingly, the magnetic material section 200 may be a laminated inductor. In an embodiment, the second laminate 210 may have a structure in which a first magnetic sheet 210a, a second magnetic sheet 210b, a third magnetic sheet 210c, a fourth magnetic sheet 210d, and a fifth magnetic sheet 210e are laminated. The second laminate 210 may be completed through a pressure process and an annealing process after the plurality of magnetic sheet 210a to 210e are laminated. Accordingly, the adjacent magnetic sheets 210a to 210e may be integrated to such an extent that boundaries between are indistinguishable.

Each of the magnetic sheets 210a to 210e may be a ferrite sheet. For example, the magnetic sheets 210a to 210e may be any one of a Ni—Zn—Cu ferrite or Ni—Zn ferrite having electrical insulation properties, but not limited thereto.

The magnetic sheets 210a to 210e may include second via holes 2101 through which a second via electrode 230 passes. In an embodiment, at least some of the second via holes 2101 of the second, third, fourth and fifth magnetic sheets 210b to 210e may be disposed to correspond to each other. Being disposed to correspond to each other may mean that each of the second via holes 2101 adjacent to each other is formed at the same position in each of the magnetic substrates 210a to 210e. Accordingly, each of the second via holes 2101 adjacent to each other may be provided on the same line. In other words, a portion of the second via holes 2101 may be vertically overlapped with each other. Further, at least some of the second via holes 2101 may be differently disposed to each other. Being differently disposed to each other may mean that each of the second via holes 2101 adjacent to each other is formed at different positions in each of the magnetic sheet 210b to 210e. Accordingly, each of the second via holes 2101 adjacent to each other may not be provided on the same line. In other words, a portion of the second via holes 2101 may not be vertically overlapped with each other. A portion of the second via holes 2101 may be disposed to correspond to the first via holes 1101. Accordingly, the first via electrode 130 and the second via electrode 230 may be electrically connected to each other.

Each of the second conductive patterns 220 may be disposed on each of the magnetic sheets 210a to 210e. For example, each of the second conductive patterns 220 may be screen printed or gravure electrode printed on each of the magnetic sheets 210a to 210e. The second conductive patterns 220 may include a metal material. For example, the second conductive patterns 220 may include any one selected from Ag, Sn, Ni, Pt, Au, Cu or an alloy thereof, but not limited thereto. In an embodiment, each 220a to 220d of the second conductive patterns 220 may have a C shape, but not limited thereto. The second conductive patterns 220 may be disposed on edges of the magnetic sheets 210a to 210e for realization of high inductance capacity.

The second via electrodes 230 may connect the adjacent second conductive patterns 220 by passing through the second via holes 2101 of the adjacent magnetic sheets 210b to 210e. Thus, the second via electrode 230 may electrically connect the adjacent second conductive patterns 220. The second via electrode 230 may include a plurality of second vias 230b to 230e. The plurality of second vias 230b to 230e may be electrically connected to each other directly or may be electrically connected to each other by the second conductive patterns 220.

In an embodiment, the second via electrode 230 may include a second upper via electrode 230e electrically connected to the first via electrode 130 directly, second lower via electrodes 230b and 230c electrically connecting the second conductive patterns 220a to 220c that are disposed on the first to third magnetic sheets 210a to 210c, and a second intermediate via electrode 230d electrically connecting the second conductive patterns 220c and 220d disposed on the third and fourth magnetic sheets 210c and 210d. The second upper via electrode 230e may be the second via 230e disposed on the second via hole 2101e of the fifth magnetic sheet 210e. The second intermediate lower via electrode 230d may be the second via 230d disposed on the second via hole 2101d of the fourth magnetic sheet 210d. The second lower via electrodes 230b and 230c may be the second vias 230b and 230c disposed on the second via holes 2101b and 2101c of the second and third magnetic sheets 210b and 210c.

The second lower via electrodes 230b and 230c may electrically connect one end of the second conductive pattern 220a disposed on the first magnetic sheet 210a, one end of the second conductive pattern 220b disposed on the second magnetic sheet 210b, and one end of the second conductive pattern 220c disposed on the third magnetic sheet 210c. The second intermediate via electrode 230d may electrically connect the other end of the second conductive pattern 220c disposed on the third magnetic sheet 210c, and the other end of the second conductive pattern 220d disposed on the fourth magnetic sheet 210d. The second upper via electrode 230e may be electrically connected to one end of the second conductive pattern 220d disposed on the fifth magnetic sheet 210e and the first via electrode 130. Since the second conductive patterns 220 are connected through the second via electrode 230, the second conductive patterns 220 may form a coil pattern in a laminate direction. The coil pattern is not specifically limited, and may be designed to be matched with the capacity of an inductor. Thus, the magnetic material section 200 may realize high inductance in the unit of μH by increasing the laminated number of the magnetic sheets 210a to 210e on which the second conductive patterns 220 are disposed. Further, the magnetic material section 200 may be miniaturized and slimmed to the extent of approximately 1 mm of thickness by being implemented in a structure in which a plurality of magnetic sheets 210a to 210e having the second conductive patterns 220 disposed thereon are laminated.

In an embodiment, the second via electrode 230 may be two, but not limited thereto. In another embodiment, the second via electrode 230 may be one, or three or more. The second via electrode 230 may be formed of a conductive material filled in the second via holes 2101 formed on each 210a to 210e of the magnetic sheets 210. The second via electrode 230 may be formed of an Ag-based conductive material or the like filled in the second via holes 2101 by a printing method. Portions 2101b to 2101c of the second via holes 2101 formed in each 210a to 210d of the magnetic sheets 210 may be disposed to correspond to each other. As illustrated in

FIG. 2, the second via electrode 230 may be electrically connected to the first via electrode 130. Since the second via electrode 230 is connected to the first via electrode 130, electric power may be supplied through the first via electrode 130.

A molding film 300 may be disposed on the first laminate 110. Accordingly, the molding film 300 may protect the electronic devices 140 mounted on the respective non-magnetic substrates 110a to 110c from an external environment. The molding film 300 may include an insulating material. For example, the molding film 300 may include a material such as silicone gel, epoxy or polyimide.

FIG. 4 is a circuit diagram illustrating a configuration of the power converting device of FIG. 1.

Referring to FIGS. 2 and 4, the power converting device according to an embodiment is a Buck converter, but not limited thereto. The Buck converter is a device including a switching device 140a, a semiconductor device 140b, a controller 140e controlling the switch 140a, an inductor 200a, a capacitor 140c or the like, and is a direct-current-to-direct-current converter for outputting voltage lower than an input voltage. The power converting device according to an embodiment may further include an input sensor 140d, and an output sensor 140f. The switching device 140a, the semiconductor device 140b, and the capacitor 140c may indicate the electronic device 140 described in FIG. 2. The inductor 200a may indicate the magnetic material section 200 described in FIGS. 1 and 2.

The semiconductor device 140b may be a Schottky battier diode (SBD) connected in parallel with a load in order to protect damage from occurring in an equipment due to charging current of the inductor 200a. The SBD may have low turn-on voltage, low resistance, and excellent reverse recovery characteristics.

The inductor 200a and the capacitor 140c may function as a low pass filter. Points A and A′ in FIG. 4 may mean that the second via electrode 230 is electrically connected to the first via electrode 130. Since the second via electrode 230 is connected to the first via electrode 130, the inductor 200a may be electrically connected to the capacitor 140c, the semiconductor device 140b and the switching device 140a.

The switching device 140a may be a Field Effective Transistor (PET) having a high driving switching frequency, but not limited thereto. Since the switching device 140a is turned on or off by a predetermined cycle, the power converting device 10 may convert an input voltage to a desired output voltage. In an embodiment, the output voltage of the power converting device 10 may be formed to be lower than the input voltage.

The input sensor 140d may sense the input voltage input from the outside through the first lead pattern 1201 (see FIG. 2). The input sensor 140d may transmit information about the sensed input voltage to the controller 140e.

The output sensor 140f may sense the output voltage output to the outside through the second lead pattern 1202 (see FIG. 2). The output sensor 140f may transmit information about the sensed output voltage to the controller 140e.

The controller 140e may control the switching device 140a. The controller 140e may control on and off operations of the switching device 140a on the basis of the input and output voltages received from the input sensor 140d and the output sensor 140f.

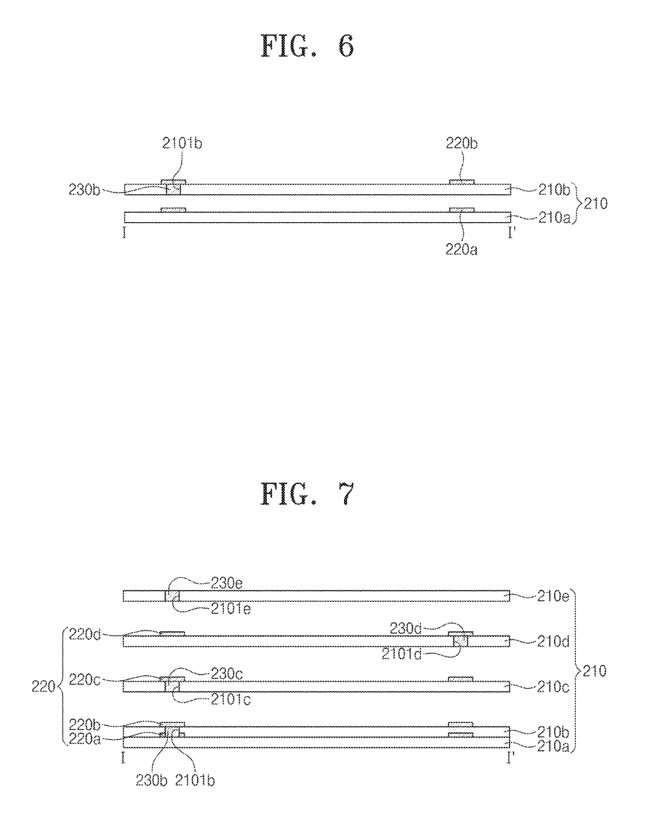

FIGS. 5 to 13 are cross sections illustrating a manufacturing process of the power converting device of FIG. 1. The cross sections illustrated in FIGS. 5 to 13 are based on the cross section taken along line I-I′ of FIG. 1.

A manufacturing process of the power converting device 10 according to an embodiment is described with reference to FIGS. 2, 3 and 5 to 13.

Referring to FIGS. 3, 5 and 6, a second conductive pattern 220a may be printed on a first magnetic sheet 210a. A second magnetic sheet 210b may be laminated on the first magnetic sheet 210a after the second conductive pattern 220a is printed on the first magnetic sheet 210a. For example, the second magnetic sheet 210b may be laminated on the first magnetic sheet 210a in a state in which the second via 230b and the second conductive pattern 220b are disposed thereon.

The second conductive pattern 220b may be disposed on the second magnetic sheet 210b. Referring to FIGS. 3, 7 and 8, a third magnetic sheet 210c may be disposed on the second magnetic sheet 210b, in which a second via 230c may be disposed in a second via hole 2101c formed at the same location as the location of the second via hole 2101b of the second magnetic sheet 210b. The second via hole 2101c of the third magnetic sheet 210c may vertically overlap with the second via hole 2101b of the second magnetic sheet 210b. The second conductive pattern 220c may be disposed on the third magnetic sheet 210c. The third magnetic sheet 210c may be laminated on the second sheet 210b in a state in which the second via 230c and the second conductive pattern 220c are disposed thereon.

A fourth magnetic sheet 210d may be disposed on the third magnetic sheet 210c, in which a second via 230d may be disposed in the second via hole 2101d formed at a different location from the location of the second via hole 2101c of the third magnetic sheet 210c. The second via hole 2101d of the fourth magnetic sheet 210d may not vertically overlap with the second via hole 2101c of the third magnetic sheet 210c. The second conductive pattern 220d may be disposed on the fourth magnetic sheet 210d. The fourth magnetic sheet 210d may be laminated on the third magnetic sheet 210c in a state in which the second via 230d and the second conductive pattern 220d are disposed thereon.

A fifth magnetic sheet 210e may be disposed on the fourth magnetic sheet 210d, in which a second via 230e may be disposed in a second via hole 2101e formed on a same location from the location of the second via hole 2101d of the fourth magnetic sheet 210d. The second via hole 2101e of the fifth magnetic sheet 210e may vertically overlap with the second via hole 2101d of the fourth magnetic sheet 210d. The fifth magnetic sheet 210e may be laminated on the fourth magnetic sheet 210d in a state in which the second via 230e is disposed thereon. As the fifth magnetic sheet 210e is laminated on the fourth magnetic sheet 210d, the magnetic material section 200 (see FIG. 1) may be manufactured.

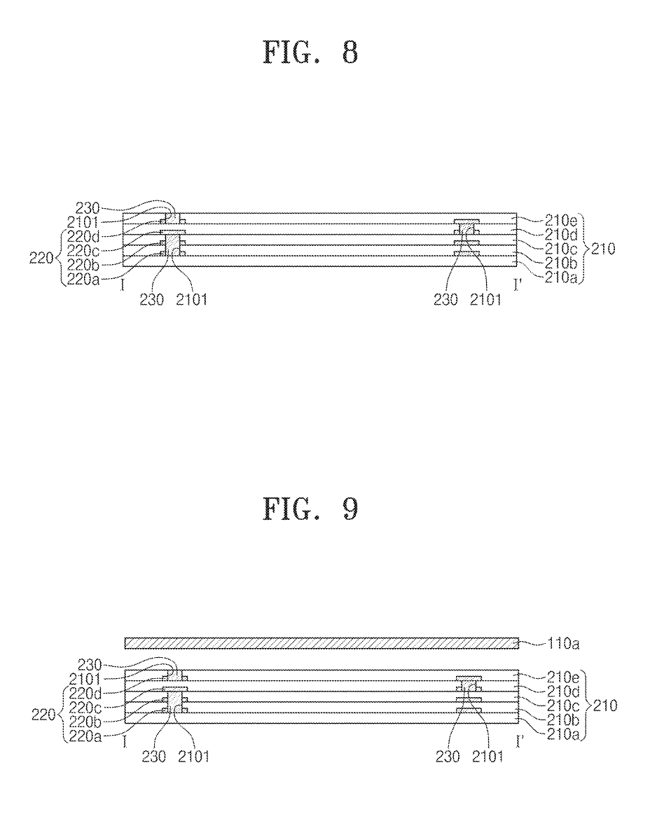

As in FIG. 8, the second via 230b disposed on the second magnetic sheet 210b and the second via 230c disposed on the third magnetic sheet 210c may be disposed to correspond to each other. In other words, the second via 230b disposed on the second magnetic sheet 210b and the second via 230c disposed on the third magnetic sheet 210c may be vertically overlapped with each other. The second via 230b of the second magnetic sheet 210b and the second via 230c of the third magnetic sheet 210c may form the second lower via electrodes 230b and 230c. Alternatively, in another embodiment, the first, second and third magnetic sheets 210a to 210c having the second conductive patterns 220a to 220c disposed thereon are laminated, and then the second and third magnetic sheets 210b to 210c may be punched by a laser or mechanical means at one time. Accordingly, the second via holes 2101b and 2101c may be formed in the second and third magnetic sheets 210b and 210c. The second via holes 2101b and 2101c formed in the second and third magnetic sheets 210b and 210c may be disposed on a same line. Forming the second via holes 2101b and 2101c in the second and third magnetic sheets 210b and 210c may reduce manufacturing time compared with forming second via holes 210 lb and 2101c in the second and third magnetic sheets 210b and 210c individually. The second lower via electrodes 230b and 230c may be formed by filling a conductive material in the second via holes 2101b and 2101c of the second and third magnetic sheets 210b and 210c.

Referring to FIG. 9, a non-magnetic substrate 110a may be laminated on the second laminate 210 after the second via electrode 230 is formed. For example, a first non-magnetic substrate 110a may be laminated on the fifth magnetic sheet 210e.

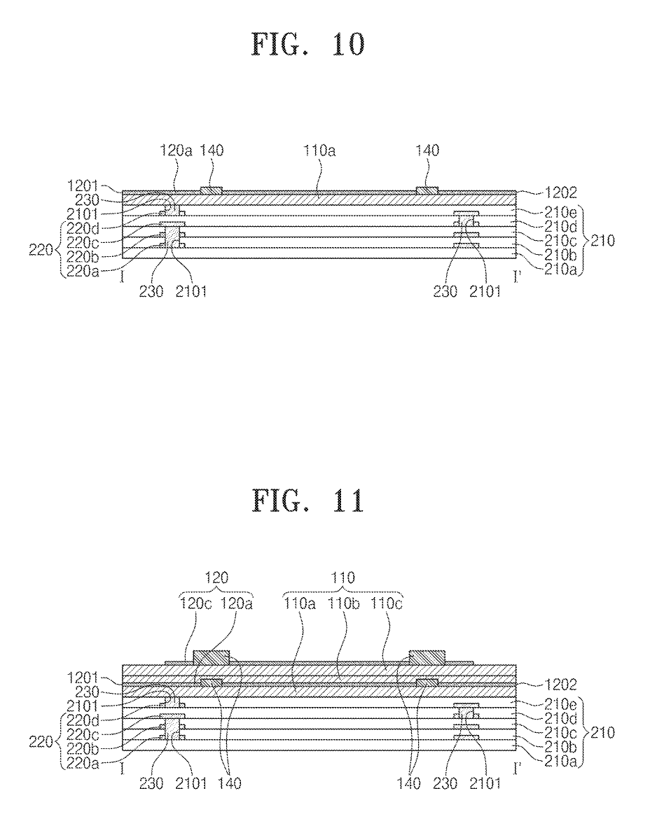

Referring to FIG. 10, at least one electronic device 140 may be mounted on the first non-magnetic substrate 110 after the first non-magnetic substrate 110a is laminated on the fifth magnetic sheet 210e. A first conductive pattern 120a may be printed on the first non-magnetic substrate 110a. The first conductive pattern 120a may be connected to the electronic device 140 directly. The first conductive pattern 120 printed on the first non-magnetic substrate 110a may include lead patterns 1201 and 1202 that are electrically connected to an external terminal (not shown).

Referring to FIG. 11, second and third non-magnetic substrates 110b and 110c may be laminated sequentially on the first non-magnetic substrate 110a after the electronic device 140 and the first conductive pattern 120a are provided on the first non-magnetic substrate 110a. Electronic devices 140 may be mounted on the third non-magnetic substrate 110c after each of the second and third non-magnetic substrates 110b and 110c is laminated on the first non-magnetic substrate 110a. Also, the first conductive pattern 120c may be printed on the third non-magnetic substrate 110c. The first conductive pattern 120c printed on the third non-magnetic substrate 110c may be directly connected to the electronic devices 140 mounted on the third non-magnetic substrate 110c.

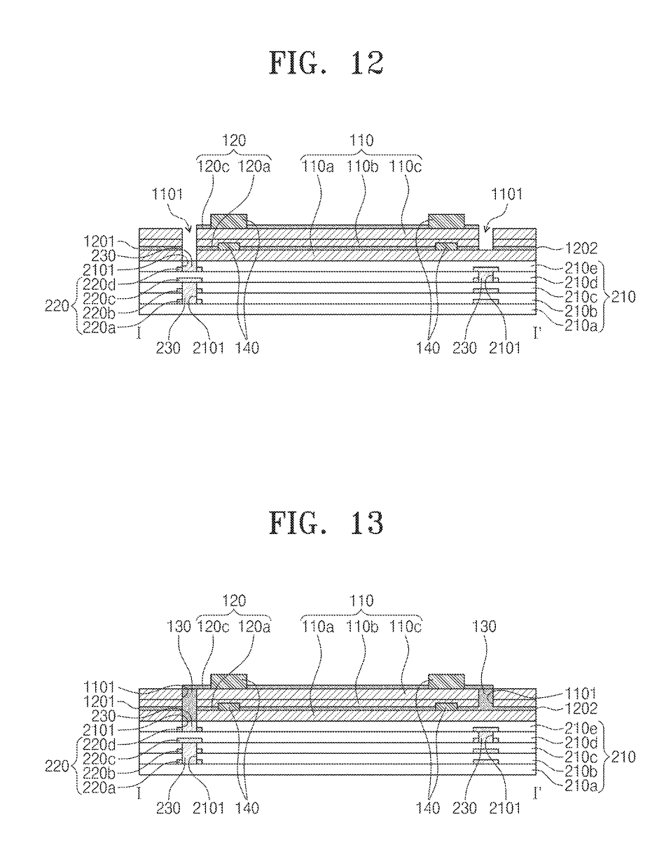

Referring to FIG. 12, the plurality of non-magnetic substrates 110a to 110c may be punched at one time by the laser or mechanical means after the electronic devices 140 and the first conductive pattern 120c are provided on the third non-magnetic substrate 110c. Accordingly, first via holes 1101 may be formed in the first, second and third non-magnetic substrates 110a to 110c. The first via holes 1101 formed in the first, second and third non-magnetic substrates 110a to 110c may be disposed on a same line. In other words, the first via holes 1101 formed in the first, second and third non-magnetic substrates 110a to 110c may be vertically overlapped with each other. Forming the first via holes 1101 in the plurality of non-magnetic substrates 110a to 110c at one time may reduce manufacturing time compared with forming the first via holes 1101 in the plurality of non-substrates 110a to 110c individually. Each of the first via holes 1101 may be formed to be disposed on the same line with a portion 2101e of the second via holes 2101.

Alternatively, in another embodiment, a first via hole (no reference numeral) may be formed in each of the first, second and third non-magnetic substrates 110a to 110c individually. For example, the first non-magnetic substrate 110a may include a first via hole formed at the same location as the second via hole 2101e of the fifth magnetic substrate 220e. A first via (no reference numeral) may be disposed in the first via hole of the first non-magnetic substrate 110a. A first conductive pattern 120a and electronic devices 140 may be disposed on the first non-magnetic substrate 110a.

The second non-magnetic substrate 110b may include a first via hole (no reference numeral) formed at the same location as the first via hole (no reference numeral) of the first non-magnetic substrate 110a. A first via (no reference numeral) may be disposed in the first via hole of the second non-magnetic substrate 110b. The second non-magnetic substrate 110b may be laminated on the first non-magnetic substrate 110a in a state in which the first via is disposed thereon.

The third non-magnetic substrate 110c may include a first via hole (no reference numeral) formed at the same location as the first via hole of the second non-magnetic substrate 110b. A first via (no reference numeral) may be disposed in the first via hole of the third non-magnetic substrate 110c. A first conductive pattern 120c and electronic devices 140 may be disposed on the third non-magnetic substrate 110c. The third non-magnetic substrate 110c may be laminated on the second non-magnetic substrate 110b in a state in which the first via, the first conductive pattern 120c and the electronic devices 140 are disposed thereon. The electronic device section 100 (see FIG. 1) may be manufactured as the third non-magnetic substrate 110c is laminated on the second non-magnetic substrate 110b.

Referring to FIG. 13, a conductive material is filled in the first via holes 1101 of the plurality of non-magnetic substrates 110a to 110c. Accordingly, a first via electrode 130 may be formed in the first via holes 1101. That is, the first via electrode 130 may be formed in the electronic device section 100 (see FIG. 1). The first via electrode 130 may be electrically connected to the second via electrode 230 directly as each of the first via holes 1101 is disposed on the same line as the second via holes 2101. Accordingly, power applied from an external power source by the first conductive pattern 120c may be applied to the second conductive patterns 220 while electric power loss is minimized. Accordingly, the electronic device section 100 (see FIG. 1) is disposed on the magnetic material section 200, and may be electrically connected to the magnetic material section 200 (see FIG. 1).

Referring to FIG. 2 again, a molding film 300 may be provided on the third non-magnetic substrate 110c after the first via electrode 130 is formed. The molding film 300 may be formed on the third non-magnetic substrate 110c by performing a chemical vapor deposition, a physical vapor deposition or an atomic layer deposition.

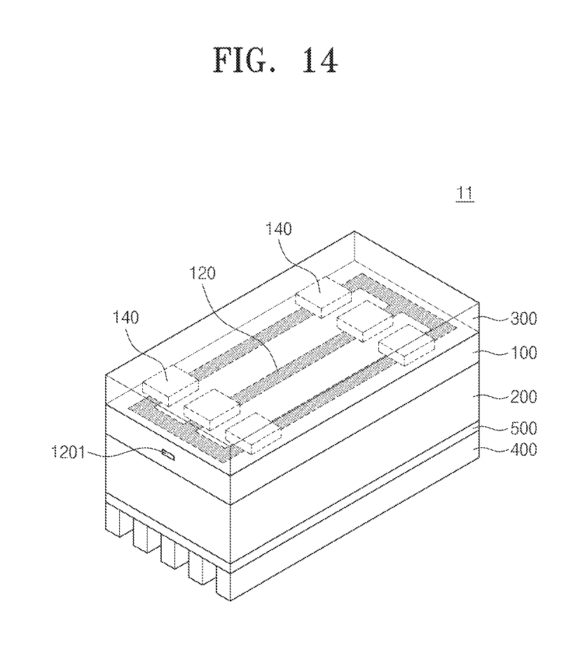

FIG. 14 is a perspective view illustrating a power converting device according to an embodiment of the inventive concept.

Referring to FIG. 14, a power converting device 11 according to an embodiment may include an electronic device section 100, a magnetic material section 200, a molding film 300, a heat sink 400, and a dummy adhesive laminate 500. The electronic device section 100 may include a first laminate 110, a first conductive pattern, and a first via electrode 130. The magnetic material section 200 may include a second laminate 210, a second conductive pattern, and a second via electrode 230. For convenience of explanation, descriptions for components that are substantially the same as those exemplified with reference to FIGS. 1 to 3 are omitted.

The heat sink 400 may be disposed on one side of the second laminate 210. For example, the heat sink 400 may be disposed under the second laminate 210 to be in contact with a lower surface of the second laminate 210. The heat sink 400 may dissipate heat generated in the second laminate 210 and/or the first laminate 110. The heat sink 400 may include a metal material having high heat conductivity. For example, the heat sink 400 may include aluminum, copper or the like.

The dummy adhesive laminate 500 may be disposed between the second laminate 210 and the heat sink 400 to bond the second laminate 210 and the heat sink 400 to each other. For example, the dummy adhesive laminate 500 may bond a ferrite sheet and the heat sink 400 to each other.

The power converting device according to the present disclosure provides the following advantageous effects.

The power converting device may be miniaturized by using a laminate type inductor in which a plurality of magnetic sheets having conductive patterns are laminated. The power converting device may be miniaturized by using a multilayer substrate having electronic devices and conductive patterns built therein.

The advantageous effects of the present disclosure are not limited to the foregoing, and other effects not described herein may be apparently understood by those skilled in the art from the appended claims.

While the present disclosure has been particularly shown and described with reference to exemplary embodiments thereof, it will be understood by those of ordinary skilled in the art that various changes may be made therein without departing from the scope of the present disclosure as defined by the following claims, and it should not be understood that these changes are separate from the technical spirit and vision of the present disclosure.

What is claimed is:

1. A power converting device comprising:
a first laminate having a plurality of non-magnetic substrates which are laminated;
electronic devices disposed on at least one of the non-magnetic substrates;
first conductive patterns disposed on the non-magnetic substrate on which the electronic devices are disposed, the first conductive patterns being connected to the electronic devices;
at least one first via electrode connecting the respective first conductive patterns to each other;
a second laminate disposed on one side of the first laminate and having a plurality of magnetic sheets which are laminated;
second conductive patterns disposed on at least two magnetic sheets among the plurality of magnetic sheets; and
at least one via electrode connecting the respective second conductive patterns to each other,
wherein the first via electrode and the second via electrode are connected to each other.

2. The power converting device in claim 1, wherein each of the magnetic sheets is a ferrite sheet.

3. The power converting device in claim 1, wherein the non-magnetic substrate is a low temperature co-fired ceramic (LTCC) substrate.

4. The power converting device in claim 1, wherein the first conductive patterns and the second conductive patterns include a metallic material.

5. The power converting device in claim 1, further comprising a heat sink disposed on one side on the second laminate.

6. The power converting device in claim 5, further comprising a dummy adhesive layer disposed between the second laminate and the heat sink to bond the second laminate and the heat sink.

7. The power converting device in claim 1, further comprising a molding film disposed on the first laminate.

8. The power converting device in claim 1, wherein at least any one of the first conductive patterns comprises a lead pattern connected to an external terminal.

9. The power converting device in claim 1, wherein at least any one of the non-magnetic substrates comprises first via holes through which the first via electrode passes, and at least any one of the magnetic sheets comprises second via holes through which the second via electrode passes.

10. The power converting device in claim 9, wherein a first via hole adjacent to the second laminate among the first via holes and a second via hole adjacent to the first laminate among the second via holes are disposed on the same line.
